(19) United States
(12) Patent Application Publication
(10) Pub. No.: US 2009/0114440 A1
(43) Pub. Date: May 7, 2009

(54) Conductive Magnetic Filler, Resin Composition Containing the Filler, Electromagnetic Interference Suppressing Sheet Using the Resin Composition and Applications Thereof, and Process for Producing the Electromagnetic Interference Suppressing Sheet

(76) Inventors: Kazumi Yamamoto, Hiroshima-ken (JP); Tetsuya Kimura, Hiroshima-ken (JP)

Correspondence Address: NIXON & VANDERHYE, PC, 901 NORTH GLEBE ROAD, 11TH FLOOR, ARLINGTON, VA, 22203, US

(21) Appl. No.: 11/883,881

(22) PCT Filed: Jan. 18, 2007
(86) PCT No.: PCT/JP2007/000018

§ 371 Date: May 2, 2008

(51) Int. Cl. H05K 9/00; H01B 1/18

(52) U.S. Cl. 174/391; 174/350; 361/818; 264/105; 252/62.56

(57) ABSTRACT

There are provided a soft magnetic material in the form of particles for suppressing occurrence of electromagnetic interference which is capable of exhibiting the suppressing effect in a broad frequency range from a low frequency band to a high frequency band, as well as an electromagnetic interference suppressing sheet using the material. When a conductive magnetic filler prepared by mixing a conductive carbon with soft magnetic particles at a volume ratio of 3 to 10:50 to 70 is highly filled in a sheet material, there can be obtained an electromagnetic interference suppressing sheet which is suitable for high-density mounting to electronic equipments, has an excellent electromagnetic absorption in a near electromagnetic field, and is fully suppressed from undergoing electromagnetic reflection thereon.

### TECHNICAL FIELD OF THE INVENTION

The present invention relates to a conductive magnetic filler comprising a blended mixture of a conductive carbon and soft magnetic particles which is blended in an electromagnetic interference suppressing sheet for preventing interference of unnecessary electromagnetic waves generated from digital electronic equipments. Also, the present invention relates to a resin composition containing the conductive magnetic filler, an electromagnetic interference suppressing sheet using the resin composition, and a process for producing the electromagnetic interference suppressing sheet. Further, the present invention relates to a flat cable for high-frequency signals and a flexible printed circuit board using the above electromagnetic interference suppressing sheet.

### BACKGROUND OF THE INVENTION

In recent years, there has been a remarkable progress of digital electronic equipments. In particular, mobile electronic equipments such as typically cellular phones, digital cameras and note-type personal computers, are remarkably required to use high-frequency signals as an actuating signal therefor and achieve reduction in size and weight thereof, and one of the largest technical problems in these equipments is a high-density mounting of electronic parts or wiring boards thereto.

With the recent progress of high-density mounting of electronic parts or wiring boards to the electronic equipments as well as the use of high frequency signals as an actuating signal therefor, the electronic parts generating noises tend to be mounted at a smaller distance from other electronic parts. Therefore, an electromagnetic interference suppressing sheet has been used for the purpose of preventing unnecessary radiation from being generated from microprocessors, LSI or liquid crystal panels of the electronic equipments. In such applications, absorption and reflection phenomena of electromagnetic waves in a near electromagnetic field are hardly analyzable by conventionally known transmission line theory in a remote electromagnetic field (in the case of a plane electromagnetic wave) (HASHIMOTO, Osamu, “Movement of Wave Absorbers”, Journal of Electronic Information Communication Institute, Vol. 86. No. 10, pp. 800 to 803, October, 2003). For this reason, the electromagnetic interference suppressing sheet has been largely designed depending upon experiences solely. Recently, there have been used electromagnetic interference suppressing sheets of such a type prepared by blending flat magnetic metal particles as soft magnetic particles in a resin for the purpose of absorbing electromagnetic waves in a near electromagnetic field (refer to Patent Documents 1 and 2).

Conventionally, there has been proposed the electromagnetic interference suppressing member having a thickness of 1.2 mm which contain flat Fe—Al—Si alloy particles (sendust particles) having an average particle diameter of 10 μm as soft magnetic particles in an amount of 90% by weight (refer to Patent Document 1). In the compositions 1 and 3 concretely proposed therein, the content of the sendust particles therein is 58.9% by volume when calculated under such conditions that a density of the alloy particles is 6.9 kg/L and a density of a resin component contained in the compositions is 1.1 kg/L.

In addition, there has been proposed the “process for producing a magnetic sheet comprising the steps of applying a magnetic coating material prepared by dispersing flat magnetic metal particles in a resin and a solvent, onto a substrate having a release layer thereon; drying the applied coating material to form a coating layer; and peeling off the coating layer from the substrate to obtain the magnetic sheet” (refer to Patent Document 2). In the magnetic shielding sheet concretely proposed therein which has a dried thickness of 120 μm and a maximum filling rate of sendust particles of 80% by weight, the content of the sendust particles in the magnetic sheet is 56.0% by volume when calculated under such conditions that a density of the sendust particles is 6.9 kg/L and a density of a resin component contained in the sheet is 1.1 kg/L. Therefore, it is suggested that the thickness of the magnetic sheet produced according to the latter production process is smaller than that produced in the former technique. The thin film-type magnetic sheets are more suitable for high-density mounting of electronic parts or wiring boards.

Patent Document 1: Japanese Patent Application Laid-open (KOKAI) No. 7-212079

Patent Document 2: Japanese Patent Application Laid-open (KOKAI) No. 2000-244171

### DISCLOSURE OF THE INVENTION

### Problem to be Solved by the Invention

With the recent progress of reduction in size and weight of digital electronic equipments, it has been strongly required to achieve a still higher-density mounting of electronic parts or wiring boards thereto, and provide an electromagnetic interference suppressing sheet capable of exhibiting a still smaller thickness, an excellent electromagnetic absorption performance in a near electromagnetic field and a less electromagnetic reflection thereon. Usually, when the thickness of the electromagnetic interference suppressing sheet is reduced, the electromagnetic absorption performance thereof tends to be deteriorated. Accordingly, in order to further reduce the thickness of the sheet, it is required to increase a content of magnetic particles therein and simultaneously ensure practical flexibility and strength of the sheet.

### Means for Solving Problem

To accomplish the aims, in a first aspect of the present invention, there is provided a conductive magnetic filler comprising a mixture comprising a conductive carbon and soft magnetic particles at a volume ratio of 3 to 10:50 to 70.

In a second aspect of the present invention, there is provided a conductive magnetic filler as described in the above first aspect, wherein the soft magnetic particles comprise particles of at least one material selected from the group consisting of carbonyl iron, magnetite, spinel ferrite, sendust, silicon steel and iron.

In a third aspect of the present invention, there is provided a resin composition which contains a conductive magnetic filler made of a mixture containing a conductive carbon and soft magnetic particles at a volume ratio of 3 to 10:50 to 70, in an amount of 53 to 80% by volume.

In a fourth aspect of the present invention, there is provided an electromagnetic interference suppressing sheet using the resin composition as described above.

In a fifth aspect of the present invention, there is provided an electromagnetic interference suppressing sheet which is produced from a resin composition containing a conductive magnetic filler made of a mixture containing a conductive carbon and soft magnetic particles at a volume ratio of 3 to 10:50 to 70, in an amount of 53 to 80% by volume, wherein when subjecting the sheet having a thickness of not more than 100 μm to microstrip line measurement, an electromagnetic absorption of the sheet is not less than 10% as measured at 500 MHz and not less than 40% as measured at 3 GHz, and an electromagnetic reflection of the sheet is not more than −5 dB as measured in the range of 100 MHz to 3 GHz.

In a sixth aspect of the present invention, there is provided a flat cable for high-frequency signals using the electromagnetic interference suppressing sheet as described above.

In a seventh aspect of the present invention, there is provided a flexible printed circuit board using the electromagnetic interference suppressing sheet as described above.

In an eighth aspect of the present invention, there is provided a process for producing an electromagnetic interference suppressing sheet, comprising the steps of applying a coating material in which the conductive magnetic filler as described above is dispersed, onto a substrate; drying the applied coating material to control a thickness of a coating layer obtained therefrom; and subjecting the obtained coated film to thermal pressure forming.

### EFFECT OF THE INVENTION

In accordance with the present invention, there can be obtained the soft magnetic particles capable of being filled with a higher density as compared to the conventional particles. When using such highly-filled soft magnetic particles, there can be obtained the electromagnetic interference suppressing sheet exhibiting an excellent electromagnetic absorption in a near electromagnetic field. According to the production process including the steps of applying the magnetic coating material using the conductive magnetic filler of the present invention onto a substrate so as to form a coating film having a dried thickness of 10 to 100 μm and then subjecting the resultant coating film to thermal pressure forming, it is possible to obtain the electromagnetic interference suppressing sheet exhibiting an excellent electromagnetic absorption in a near electromagnetic field and a less reflection of electromagnetic waves thereon which is suitable for high-density mounting.

### PREFERRED EMBODIMENTS FOR CARRYING OUT THE INVENTION

The soft magnetic particles used in the present invention are particles of at least one material selected from the group consisting of carbonyl iron, magnetite, spinel ferrite, sendust, silicon steel and iron. These particles may have any suitable shape such as a granular shape, a spherical shape, a crushed shape and an acicular shape.

The soft magnetic particles used in the present invention have an average particle diameter which is preferably not more than ⅓ time and more preferably not more than ⅕ time a thickness of the resultant sheet. When the average particle diameter of the soft magnetic particles is more than ⅓ time the sheet thickness, the resultant electromagnetic interference suppressing sheet tends to be deteriorated in surface smoothness, resulting in poor adhesion of the sheet to an electromagnetic wave generating source and, therefore, deterioration in electromagnetic absorption performance thereof.

The soft magnetic particles used in the present invention preferably have a density of 4.0 to 9.0 g/cm³ and more preferably 5.0 to 8.0 g/cm³.

Among the soft magnetic particles used in the present invention, carbonyl iron particles preferably have a spherical shape and an average particle diameter of 1 to 10 μm since such particles are capable of being filled with a high density and uniformly dispersed in resins. When the average particle diameter of the carbonyl iron particles is less than 1 μm, the resultant resin mixture tend to have a high viscosity, thereby failing to allow the particles to be uniformly dispersed therein. The carbonyl iron particles having an average particle diameter of more than 10 μm tend to be hardly filled in resins with a high density. The average particle diameter of the carbonyl iron particles is more preferably 2 to 8 μm.

The soft magnetic particles used in the present invention may be subjected to a surface treatment with a titanate-based coupling agent or a silane-based coupling agent, if required, though such a surface treatment is not essential. The metal-based soft magnetic particles are preferably surface-treated with a phosphoric acid-based compound. Further, the soft magnetic particles may also be surface-treated with the coupling agent in an amount of 0.1 to 1.0% by weight on the basis of the weight of the soft magnetic particles. When the amount of the coupling agent used upon the surface treatment is less than 0.1% by weight, it may be difficult to fully enhance an affinity of the soft magnetic particles to resins, thereby failing to ensure a sufficient oxidation stability thereof. When the amount of the coupling agent used upon the surface treatment is more than 1.0% by weight, the resultant sheet tends to exhibit a too high impedance, resulting in deteriorated electromagnetic absorption thereof. The amount of the coupling agent used upon the surface treatment is preferably 0.1 to 0.5% by weight.

Examples of the titanate-based coupling agent may include isopropyl tristearoyl titanate, isopropyl tris(dioctyl pyrophosphate)titanate, isopropyl tri(N-aminoethyl-aminoethyl)titanate, tetraoctyl bis(ditridecyl phosphate)titanate, tetra(2,2-diallyloxymethyl-1-butyl)bis(ditridecyl)phosphate titanate, bis(dioctyl pyrophosphate)oxyacetate titanate and bis(dioctyl pyrophosphate)ethylene titanate.

Examples of the silane-based coupling agent may include those compounds suitable as a coupling agent for elastomers such as vinyl trichlorosilane, vinyl trimethoxysilane, vinyl triethoxysilane, 2-(3,4-epoxycyclohexyl)ethyl trimethoxysilane, 3-glycidoxypropyl trimethoxysilane, 3-glycidoxypropylmethyl diethoxysilane, 3-glycidoxypropyl triethoxysilane, 3-methacryloxypropylmethyl dimethoxysilane, 3-methacryloxypropyl trimethoxysilane, 3-methacryloxypropylmethyl diethoxysilane, 3-methacryloxypropyl triethoxysilane, 3-acryloxypropyl trimethoxysilane, N-2-(aminoethyl)-3-aminopropylmethyl dimethoxysilane, N-2-(aminoethyl)-3-aminopropyl trimethoxysilane, N-2-(aminoethyl)-3-aminopropyl triethoxysilane, 3-aminopropyl trimethoxysilane, 3-aminopropyl triethoxysilane, 3-mercaptopropylmethyl dimethoxysilane, 3-mercaptopropyl trimethoxysilane and bis(triethoxysilylpropyl)tetrasulfide.

Also, the metal-based soft magnetic particles are preferably surface-treated with a phosphoric acid-based compound. The amount of the phosphoric acid-based compound used for the surface treatment is 0.1 to 0.5% by weight (calculated as phosphoric acid) on the basis of the weight of the soft magnetic particles. Further, the soft magnetic particles may be surface-treated with the silane coupling agent in an amount of 0.1 to 1.0% by weight on the basis of the weight of the soft magnetic particles. When the amount of the phosphoric acid-based compound used for the surface treatment is less than 0.1% by weight, the resultant sheet tends to be deteriorated in oxidation stability and lowered in impedance, resulting in increased reflection thereon. When the amount of the phosphoric acid-based compound used for the surface treatment is more than 0.5% by weight, the resultant sheet tends to exhibit a too high impedance, resulting in deteriorated electromagnetic absorption thereof. The amount of the phosphoric acid-based compound used for the surface treatment is preferably 0.1 to 0.4% by weight.

In the present invention, as the conductive carbon, there may be suitably used conductive carbon black or fibrous carbon prepared by processing carbon fibers.

The conductive carbon black preferably has a particle diameter of 20 to 60 nm and a BET specific surface area of 30 to 1300 m²/g. More preferably, as the conductive carbon black, there is used a high-conductive carbon black of a hollow shell structure exhibiting a particle diameter of 30 to 40 nm and a BET specific surface area of 700 to 1300 m²/g.

As the fibrous carbon prepared by processing carbon fibers, there may be suitably used cut fibers having a fiber length of 3 to 24 mm or milled fibers having a fiber length of 30 to 150 μm. Further, it is preferred that the fibrous carbon after processed into the electromagnetic interference suppressing sheet has a fiber length of about 10 μm to about 10 mm when the surface of the sheet is observed by a scanning electron microscope. When the fiber length of the fibrous carbon is less than 10 μm, the resultant sheet tends to be deteriorated in electromagnetic absorption performance when flexed or bent. When the fiber length of the fibrous carbon is more than 10 mm, the resultant sheet tends to suffer from occurrence of fuzzes, resulting in poor handling property. The fiber length of the fibrous carbon after process into the sheet is more preferably about 30 μm to about 3 mm.

The volume ratio of the conductive carbon to the soft magnetic particles used in the present invention is in the range of 3 to 10:50 to 70. When the volume ratio of the conductive carbon to the soft magnetic particles is less than the above specified range, the resultant sheet tends to be lowered in electromagnetic absorption. When the volume ratio of the conductive carbon to the soft magnetic particles is more than the above specified range, the resultant sheet tends to exhibit a large reflection of electromagnetic waves thereon, resulting in deteriorated sheet strength and flexibility. The volume ratio of the conductive carbon to the soft magnetic particles is preferably 3 to 10:55 to 70 and more preferably 4 to 8:60 to 70.

Next, the electromagnetic interference suppressing sheet of the present invention is described.

The electromagnetic interference suppressing sheet of the present invention preferably contains the conductive magnetic filler of the present invention in an amount of 53 to 80% by volume, and has a thickness of not more than 50 μm. When the content of the conductive magnetic filler in the sheet is less than 53% by weight, the resultant sheet tends to be lowered in electromagnetic absorption. Also, when the content of the carbonyl iron particles as the conductive magnetic filler in the sheet is more than 80% by volume, the resultant sheet tends to show a large reflection of electromagnetic waves thereon, resulting in deteriorated sheet strength and flexibility. The thickness of the sheet may be adjusted depending upon used conditions of the sheet. When the thickness is less than 10 μm, the resultant sheet tends to be insufficient in strength. When the thickness is more than 100 μm, the sheet tends to have a too large thickness for electronic circuits to be used in a high-density mounting.

The electromagnetic interference suppressing sheet of the present invention preferably contains a resin component in an amount of 15 to 30% by volume. When the content of the resin component in the sheet is less than 15% by volume, the resultant sheet tends to be deteriorated in flexing property. When the content of the resin component in the sheet is more than 30% by volume, the resultant sheet tends to be deteriorated in electromagnetic absorption. Examples of the resin component used in the present invention may include styrene-based elastomers, olefin-based elastomers, polyester-based elastomers, polyamide-based elastomers, urethane-based elastomers, silicone-based elastomers, etc. Specific examples of the styrene-based elastomers may include SEBS (styrene-ethylene-butylene-styrene block copolymers). These elastomers may be used in the form of a mixture with an acrylic resin, an epoxy resin, a polyolefin resin, etc.

The electromagnetic interference suppressing sheet of the present invention may also suitably contain a flame retardant in an amount of 5 to 20% by volume. When the content of the flame retardant in the sheet is less than 5% by volume, the resultant sheet may fail to exhibit a sufficient flame retarding effect. When the content of the flame retardant in the sheet is more than 20% by volume, the resultant sheet tends to be lowered in electromagnetic absorption. Examples of the flame retardant may include melamine polyphosphate, magnesium hydroxide, hydrotalcite, etc. Among these flame retardants, preferred are magnesium hydroxide and melamine polyphosphate.

The electromagnetic interference suppressing sheet of the present invention may also suitably contain an antioxidant in an amount of 0.5 to 3% by volume. When the content of the antioxidant in the sheet is less than 0.5% by volume, the resultant sheet may fail to exhibit a sufficient oxidation resistance. When the content of the antioxidant in the sheet is more than 3% by volume, the resultant sheet tends to be lowered in electromagnetic absorption. Examples of the antioxidant may include 2′,3-bis[3-(3,5-di-tert-butyl-4-hydroxyphenyl)propionyl]propionohydrazide (“IRGANOX MD1024” produced by Ciba Specialty Chemicals Corp.). As the antioxidant for resins, tetrakis[methylene-3-(3′,5′-di-tert-butyl-4′-hydroxyphenyl)propionate], tris-(3,5-di-tert-butyl-4-hydroxybenzyl)isocyanurate and N,N′-hexamethylene bis(3,5-di-tert-butyl-4-hydroxyhydrocinnamide) may be selectively used according to the resin used. AS the antioxidant for rubber-based resins, there may be suitably used “CTPI” (N-cyclohexylthiophthalimide) produced by Toray Co., Ltd.

The electromagnetic interference suppressing sheet of the present invention exhibits preferably an electromagnetic absorption of not less than 10% as measured at 0.5 GHz and not less than 40% as measured at 3 GHz, when the sheet having a thickness of 100 μm is subjected to the measurements. When the electromagnetic absorption of the sheet is less than these specified values, the amount of electromagnetic waves absorbed by the sheet tends to be insufficient.

The electromagnetic interference suppressing sheet of the present invention exhibits preferably an electromagnetic reflection of not more than −5 dB as measured in the range of 0.1 to 3 GHz, when the sheet having a thickness of 100 μm is subjected to the measurement. When the electromagnetic reflection of the sheet is more than the above specified value, the amount of electromagnetic waves reflected on the sheet tends to be too large.

Next, the flat cable for high-frequency signals and the flexible printed circuit board according to the present invention are described.

In the flat cable for high-frequency signals and the flexible printed circuit board according to the present invention, the electromagnetic interference suppressing sheet of the present invention is used to realize reduction in size of the substrate and less generation of noises from the wiring board itself as the noise-irradiation source. This enables production of high-density electronic circuits, decrease in actuating voltage and increase in actuating current therefor, thereby providing a substrate or board having a good noise resistance.

In the process for producing the electromagnetic interference suppressing sheet according to the present invention, a magnetic coating material in which the conductive magnetic filler of the present invention is dispersed, is applied onto a substrate, and then dried to control a thickness of the resultant magnetic sheet. Then, the thus obtained magnetic sheet is suitably subjected to thermal pressure forming. The use of such a magnetic coating material is preferable since the conductive magnetic filler can be highly filled and uniformly dispersed therein.

### EXAMPLES

The methods for measuring various properties described in the following examples are as follows.

### <Density of Particles>

The density of particles was measured by the following method. Using a density meter “MULTIVOLUME DENSIMETER 1305 MODEL” manufactured by Micromeritex Inc., 28 g (W) of the particles were charged into a weighing cell to measure a sample volume (V) under a helium gas pressure and determine the density thereof according to the following formula:

Density=W/V(g/cm³)

### <Measurement of Electromagnetic Absorption and Electromagnetic Reflection>

The measurements of electromagnetic absorption and electromagnetic reflection were performed by using a substrate provided thereon with a microstrip line having a length of 100 mm, a width of 2.3 mm and a thickness of 35 μm whose impedance was adjusted to 50Ω. The sheet to be measured was cut to form a test specimen having a width of 40 mm and a length of 50 mm.

The microstrip line was connected to a network analyzer “8720D” manufactured by Hewlett Packard Inc., to measure S parameters thereof. More specifically, the microstrip line and the sheet were fitted to the analyzer such that the length direction of the microstrip line was consistent with the length direction of the sheet, and the centers of the microstrip line and the sheet were aligned with each other. Then, a 10 mm-thick foamed polystyrene plate having an expansion ratio of 20 to 30 times and the same size as that of the sheet was overlapped on the sheet, and while placing a load of 300 g on the foamed polystyrene plate, the S parameters of the microstrip line were measured. From the thus measured S parameters, the electromagnetic absorption (%) and the electromagnetic reflection (dB) were calculated according to the following formulae:

Electromagnetic Absorption=(1−|S₁₁|²−|S₂₁|²)/1×100(%)

Electromagnetic Reflection=20 log |S₁(dB)

### Example 1

A solution prepared by dissolving 20% by weight of a styrene elastomer (density: 0.9 g/cm³) in cyclohexanone (“TF-4200E” produced by Hitachi Chemical Co., Ltd.), spherical magnetite “MAT305” (density: 5.0 g/cm³; particle diameter: 0.25 μm) produced by Toda Kogyo Corporation, granular conductive carbon “KETJEN BLACK EC” (density: 1.6 g/cm³) produced by KETJEN BLACK INTERNATIONAL COMPANY, melamine polyphosphate as a flame retardant “MPP-A” (density: 1.8 g/cm³) produced by SANWA Chemical Co., Ltd., and magnesium hydroxide “KISUMA 5A” (density: 2.4 g/cm³) produced by Kyowa Chemical Industry Co., Ltd., were weighed and mixed with each other such that the volume ratios of the respective materials contained in the mixture obtained after removing the solvent therefrom were 55% by volume for the spherical magnetite; 21% by volume for the styrene elastomer; 8% by volume for the granular conductive carbon; 8% by volume for the flame retardant; and 8% by volume for the magnesium hydroxide. Then, the obtained mixture was stirred using a power homogenizer manufactured by SMT Inc., at a rotating speed of 15000 rpm for 60 min, thereby obtaining a slurry. Upon stirring, ethyl cyclohexane having the same volume as that of the elastomer solution was added to the mixture to control a viscosity of the slurry. The thus obtained slurry was subjected to vacuum defoaming treatment and then applied onto a carrier film using a doctor blade. The applied slurry was dried to remove the organic solvent therefrom, thereby producing a sheet having a thickness of 80 μm. Further, the thus obtained sheet was molded at 130° C. under 90 MPa for 5 min, thereby obtaining a sheet having a thickness of 30 μm. The thus obtained sheet had a smooth surface and exhibited an excellent flexing property. In addition, using a microstrip line having a length of 100 mm, a width of 2.3 mm, a thickness of 35 μm and an impedance of 50Ω, S parameters of the microstrip line were measured using a network analyzer to calculate electromagnetic absorption and electromagnetic reflection of the sheet from the measured values. As a result, it was confirmed that the resultant sheet had an electromagnetic absorption of 15% at 500 MHz and 45% at 3 GHz and an electromagnetic reflection of not more than −10 dB in the range of 100 MHz to 3 GHz and, therefore, exhibited a high electromagnetic absorption and a low electromagnetic reflection in a broad frequency range, i.e., excellent balance between these electromagnetic properties. The composition of the obtained sheet is shown in Table 1, and the results of evaluation thereof are shown in Table 2.

### Example 2

The same procedure as defined in Example 1 was conducted to produce a sheet having a thickness of 35 μm after the heat compression molding which was composed of 6% by volume of fibrous conductive carbon “Cut Fiber Trayca TS12 006-C” (fiber length: 6 mm; fiber diameter: 1 μm; density: 1.5 g/cm³) produced by Toray Industries, Inc., 60% by volume of spherical magnetite “MAT305”, 8% by volume of melamine polyphosphate “MPP-A” (density: 1.8 g/cm³) as a flame retardant produced by SANWA Chemical Co., Ltd., and 8% by volume of magnesium hydroxide “KISUMA 5A” (density: 2.4 g/cm³) produced by Kyowa Chemical Industry Co., Ltd. Using a microstrip line, the properties of the thus obtained sheet were evaluated from S parameters thereof. As a result, it was confirmed that the resultant sheet had an electromagnetic absorption of 14% at 500 MHz and 47% at 3 GHz and an electromagnetic reflection of not more than −10 dB in the range of 100 MHz to 3 GHz and, therefore, exhibited a high electromagnetic absorption and a low electromagnetic reflection in a broad frequency range, i.e., excellent balance between these electromagnetic properties. The composition of the obtained sheet is shown in Table 1, and the results of evaluation thereof are shown in Table 2.

### Example 3

The same procedure as defined in Example 1 was conducted to produce a sheet having a thickness of 47 μm after the heat-compression molding which was composed of 4% by volume of fibrous conductive carbon “Cut Fiber Trayca TS12 006-C” (fiber length: 6 mm; fiber diameter: 1 μm; density: 1.5 g/cm³) produced by Toray Industries, Inc., 35% by volume of carbonyl iron “R1470” (particle diameter: 6.2 μm; density: 7.8 g/cm³) produced by Internal Specialty Products Inc., 23% by volume of carbonyl iron “S3000” (particle diameter: 2 μm; density: 7.6 g/cm³) produced by Internal Specialty Products Inc., 8% by volume of melamine polyphosphate “MPP-A” (density: 1.8 g/cm³) as a flame retardant produced by SANWA Chemical Co., Ltd., and 8% by volume of magnesium hydroxide “KISUMA 5A” (density: 2.4 g/cm³) produced by Kyowa Chemical Industry Co., Ltd. Using a microstrip line, the properties of the thus obtained sheet were evaluated from S parameters thereof. As a result, it was confirmed that the resultant sheet had an electromagnetic absorption of 21% at 500 MHz and 49% at 3 GHz and an electromagnetic reflection of not more than −14 dB in the range of 100 MHz to 3 GHz and, therefore, exhibited a high electromagnetic absorption and a low electromagnetic reflection in a broad frequency range, i.e., excellent balance between these electromagnetic properties. The composition of the obtained sheet is shown in Table 1, and the results of evaluation thereof are shown in Table 2.

### Examples 4, 5, 7 and 8

Sheets having the respective compositions and thicknesses as shown in Table 1 were produced by the same method as defined in Example 1. Using a microstrip line, the electromagnetic absorption and reflection of the thus obtained sheets were determined from S parameters thereof. As a result, it was confirmed that all of the resultant sheets had a thickness of not more than 100 μm, an electromagnetic absorption of not less than 10% at 500 MHz and not less than 40% at 3 GHz and an electromagnetic reflection of not more than −5 dB in the range of 100 MHz to 3 GHz and, therefore, exhibited a high electromagnetic absorption and a low electromagnetic reflection in a broad frequency range, i.e., excellent balance between these electromagnetic properties. Meanwhile, the carbonyl iron “S1641” produced by Internal Specialty Products Inc., had a particle diameter of 6.2 μm and a density of 7.6 g/cm³. The compositions of the obtained sheets are shown in Table 1, and the results of evaluation thereof are shown in Table 2.

### Examples 6 and 9 to 13

Sheets having the respective compositions and thicknesses as shown in Table 1 were produced by the same method as defined in Example 1. Using a microstrip line, the electromagnetic absorption and reflection of the thus obtained sheets were determined from S parameters thereof. As a result, it was confirmed that all of the resultant sheets had a thickness of not more than 100 μm, an electromagnetic absorption of not less than 10% at 500 MHz and not less than 40% at 3 GHz and an electromagnetic reflection of not more than −5 dB in the range of 100 MHz to 3 GHz and, therefore, exhibited a high electromagnetic absorption and a low electromagnetic reflection in a broad frequency range, i.e., excellent balance between these electromagnetic properties. Meanwhile, the Ni—Zn ferrite “BSN714” produced by Toda Kogyo Corporation, had a density of 5.1 g/cm³. The compositions of the obtained sheets are shown in Table 1, and the results of evaluation thereof are shown in Table 2.

### Comparative Example 1

The same procedure as defined in Example 1 was conducted to produce a sheet containing flat metal particles having a weight ratio between iron, aluminum and silicon of 85:6:9, an aspect ratio of 15 to 20, a density of 6.9 g/cm³ and average particle diameter of 50 μm in an amount of 47% by volume whose thickness after the heat-compression molding was adjusted to 100 μm. As a result, it was confirmed that the resultant sheet had an electromagnetic absorption of 10% at 500 MHz and 43% at 3 GHz and an electromagnetic reflection of not more than −10 dB in the range of 100 MHz to 3 GHz and, therefore, exhibited excellent balance between the electromagnetic absorption and reflection. However, notwithstanding the thickness of the sheet was as large as 100 μm, the electromagnetic absorption of the sheet was considerably deteriorated as compared to that obtained in Example 8. The composition of the obtained sheet are shown in Table 3, and the results of evaluation thereof are shown in Table 4.

### Comparative Example 2

In Comparative Example 2, a sheet having the same composition as that obtained in Comparative Example 1 whose thickness was adjusted to 500 μm was produced. The results are shown in Table 1. The resultant sheet had good electromagnetic absorption and reflection characteristics, but was unsuitable for practical use in high-density mounting owing to the large thickness of 500 μm. The composition of the obtained sheet is shown in Table 3, and the results of evaluation thereof are shown in Table 4.

### Comparative Examples 3 to 11

In Comparative Examples 3 to 11, sheets having the respective compositions and thicknesses as shown in Table 1 were produced by the same method as defined in Example 1. The sheets obtained in Comparative Examples 3 to 9 all had an electromagnetic reflection of not more than −20 dB. However, these sheets had an electromagnetic absorption of less than 10% at 500 MHz and less than 26% at 3 GHz. Namely, in Comparative Examples 3 to 9, there were obtained only electromagnetic interference suppressing sheets having a less electromagnetic absorption. The compositions of the sheets obtained in Comparative Examples 3 to 9 are shown in Table 3, and the results of evaluation thereof are shown in Table 4.

Also, in Comparative Examples 10 and 11, sheets having the respective compositions and thicknesses shown in Table 1 were produced by the same method as defined in Example 1. In Comparative Example 10, the fiber component was not well dispersed, so that the resultant coating composition was incapable of being applied to the carrier film. Whereas, in Comparative Example 11, the resultant sheet had a good electromagnetic absorption such as 33% at 500 MHz and 90% at GHz, but exhibited an electromagnetic reflection as large as −4.5 dB, resulting in problems concerning transmission of signals. The compositions of the sheets obtained in Comparative Examples 10 and 11 are shown in Table 3, and the results of evaluation thereof are shown in Table 4.

TABLE 1

| | Conductive | | | Carbonyl ion | | |
|---|---|---|---|---|---|---|
| | carbon | | Magnetite | particles | | |
| Examples | A | B | MAT305 | R1470 | S3000 | S1641 |
| Example 1 | 8 | — | 55 | — | — | — |
| Example 2 | — | 5 | 60 | — | — | — |
| Example 3 | — | 4 | — | 35 | 23 | — |
| Example 4 | — | 4 | — | 55 | — | — |
| Example 5 | — | 4 | — | 55 | — | — |
| Example 6 | 8 | — | — | — | — | — |
| Example 7 | — | 6 | — | — | — | 55 |
| Example 8 | — | 6 | — | — | — | 55 |
| Example 9 | 3.5 | — | — | 57 | — | — |
| Example 10 | 5 | — | — | 35 | 23 | — |
| Example 11 | 6 | — | — | — | — | 57 |
| Example 12 | 8.5 | — | — | — | — | — |
| Example 13 | 7.5 | — | — | — | — | — |

| | | | | 3% silicon |
|---|---|---|---|---|
| | | Sendust | Sendust | steel |
| | Ferrite | Flat | Granular | Granular |
| Examples | BSN714 | shape | shape | shape |
| Example 1 | — | — | — | — |
| Example 2 | — | — | — | — |
| Example 3 | — | — | — | — |
| Example 4 | — | — | — | — |
| Example 5 | — | — | — | — |
| Example 6 | 60 | — | — | — |
| Example 7 | — | — | — | — |
| Example 8 | — | — | — | — |
| Example 9 | — | — | — | — |
| Example 10 | — | — | — | — |
| Example 11 | — | — | — | — |
| Example 12 | — | — | 55 | — |
| Example 13 | — | — | — | 55 |

| | Total amount | Flame retardant | | Thickness |
|---|---|---|---|---|
| | of fillers | Melamine | Magnesium | of sheet |
| Examples | (vol %) | polyphosphate | hydroxide | (μm) |
| Example 1 | 63 | 8 | 8 | 30 |
| Example 2 | 65 | 8 | 8 | 35 |
| Example 3 | 62 | 8 | 8 | 47 |
| Example 4 | 59 | 8 | 8 | 50 |
| Example 5 | 59 | 8 | 8 | 100 |
| Example 6 | 68 | 8 | 8 | 50 |
| Example 7 | 61 | 8 | 8 | 50 |
| Example 8 | 61 | 8 | 8 | 100 |
| Example 9 | 60.5 | 8.5 | 8 | 50 |
| Example 10 | 63 | 8 | 9 | 50 |
| Example 11 | 63 | 8 | 8 | 50 |
| Example 12 | 63.5 | 8 | 8 | 80 |
| Example 13 | 62.5 | 8 | 8 | 80 |

Note:
A: KETJEN BLACK EC
B: Cut Fiber “TS12-006C”

TABLE 2

| | |
|---|---|
| Electromagnetic | Electromagnetic |
| absorption (%) | reflection (dB) |

| Examples | at: 0.5 GHz | at: 3 GHz | at: 0.1-3 GHz |
|---|---|---|---|
| Example 1 | 15 | 45 | −10 |
| Example 2 | 14 | 47 | −10 |
| Example 3 | 21 | 49 | −14 |
| Example 4 | 30 | 70 | −11 |
| Example 5 | 32 | 90 | −7 |
| Example 6 | 11 | 40 | −13 |
| Example 7 | 10 | 45 | −11 |
| Example 8 | 22 | 88 | −8 |
| Example 9 | 30 | 75 | −10 |
| Example 10 | 35 | 80 | −8 |
| Example 11 | 20 | 63 | −9 |
| Example 12 | 15 | 51 | −10 |
| Example 13 | 15 | 42 | −10 |

TABLE 3

| | Conductive | | | Carbonyl ion | | |
|---|---|---|---|---|---|---|
| Comparative | carbon | | Magnetite | particles | | |
| Examples | A | B | MAT305 | R1470 | S3000 | S1641 |
| Comparative | — | — | — | — | — | — |
| Example 1 | | | | | | |
| Comparative | — | — | — | — | — | — |
| Example 2 | | | | | | |
| Comparative | — | — | — | 65 | — | — |
| Example 3 | | | | | | |
| Comparative | — | — | 56.5 | — | — | — |
| Example 4 | | | | | | |
| Comparative | — | 2 | — | — | — | — |
| Example 5 | | | | | | |
| Comparative | — | 2 | — | — | — | 62 |
| Example 6 | | | | | | |
| Comparative | — | 2 | — | 60 | — | — |
| Example 7 | | | | | | |
| Comparative | 2 | — | — | — | — | 62 |
| Example 8 | | | | | | |
| Comparative | 2 | — | — | — | — | — |
| Example 9 | | | | | | |
| Comparative | — | 15 | — | 55 | — | — |
| Example 10 | | | | | | |
| Comparative | 15 | — | — | 55 | — | — |
| Example 11 | | | | | | |

| | | | | 3% silicon |
|---|---|---|---|---|
| | | Sendust | Sendust | steel |
| Comparative | Ferrite | Flat | Granular | Granular |
| Examples | BSN714 | shape | shape | shape |
| Comparative | — | 47 | — | — |
| Example 1 | | | | |
| Comparative | — | 47 | — | — |
| Example 2 | | | | |
| Comparative | — | — | — | — |
| Example 3 | | | | |
| Comparative | — | — | — | — |
| Example 4 | | | | |
| Comparative | 65 | — | — | — |
| Example 5 | | | | |
| Comparative | — | — | — | — |
| Example 6 | | | | |
| Comparative | — | — | — | — |
| Example 7 | | | | |
| Comparative | — | — | — | — |
| Example 8 | | | | |
| Comparative | — | — | 55 | — |
| Example 9 | | | | |
| Comparative | — | — | — | — |
| Example 10 | | | | |
| Comparative | — | — | — | — |
| Example 11 | | | | |

| | Total amount | Flame retardant | | Thickness |
|---|---|---|---|---|
| Comparative | of fillers | Melamine | Magnesium | of sheet |
| Examples | (vol %) | polyphosphate | hydroxide | (μm) |
| Comparative | 47 | — | — | 100 |
| Example 1 | | | | |
| Comparative | 47 | — | — | 500 |
| Example 2 | | | | |
| Comparative | 65 | — | — | 50 |
| Example 3 | | | | |
| Comparative | 56.5 | — | — | 50 |
| Example 4 | | | | |
| Comparative | 67 | — | — | 50 |
| Example 5 | | | | |
| Comparative | 64 | — | — | 50 |
| Example 6 | | | | |
| Comparative | 62 | — | — | 50 |
| Example 7 | | | | |
| Comparative | 64 | — | — | 50 |
| Example 8 | | | | |
| Comparative | 57 | — | — | 50 |
| Example 9 | | | | |
| Comparative | 70 | — | — | Not formed |
| Example 10 | | | | into sheet |
| Comparative | 70 | — | — | 50 |
| Example 11 | | | | |

Note:
A: KETJEN BLACK EC
B: Cut Fiber “TS12-006C”

TABLE 4

| | Electromagnetic | | Electromagnetic |
|---|---|---|---|
| Comparative | absorption (%) | | reflection (dB) |
| Examples | at: 0.5 GHz | at: 3 GHz | at: 0.1-3 GHz |
| Comparative | 10 | 43 | −10 |
| Example 1 | | | |
| Comparative | 20 | 85 | −7 |
| Example 2 | | | |
| Comparative | 2 | 16 | −23 |
| Example 3 | | | |
| Comparative | 3 | 12 | −23 |
| Example 4 | | | |
| Comparative | 4 | 18 | −23 |
| Example 5 | | | |
| Comparative | 4 | 19 | −24 |
| Example 6 | | | |
| Comparative | 4 | 26 | −20 |
| Example 7 | | | |
| Comparative | 6 | 30 | −14 |
| Example 8 | | | |
| Comparative | 5 | 26 | −20 |
| Example 9 | | | |
| Comparative | Unmeasurable | Unmeasurable | Unmeasurable |
| Example 10 | | | |
| Comparative | 33 | 90 | −4.5 |
| Example 11 | | | |

### INDUSTRIAL APPLICABILITY

The conductive magnetic filler of the present invention can exhibit excellent electromagnetic absorption characteristics and a less reflection of electromagnetic waves even when the thickness of the sheet is small, and is, therefore, suitable as a filler for electromagnetic interference suppressing sheets.

Also, the electromagnetic interference suppressing sheet of the present invention can exhibit a high electromagnetic absorption and a less electromagnetic reflection in a boarder frequency range, i.e., excellent balance between these electromagnetic properties, even when the sheet has a small thickness. Therefore, the sheet of the present invention can be suitably used as an electromagnetic interference suppressing sheet having excellent electromagnetic absorption characteristics in a near electromagnetic field and a less reflection of electromagnetic waves thereon.

1. A conductive magnetic filler comprising a mixture comprising a conductive carbon and soft magnetic particles at a volume ratio of 3 to 10:50 to 70.

2. A conductive magnetic filler according to claim 1, wherein the soft magnetic particles comprise particles of at least one material selected from the group consisting of carbonyl iron, magnetite, spinel ferrite, sendust, silicon steel and iron.

3. A resin composition containing the conductive magnetic filler as defined in claim 1 in an amount of 53 to 80% by volume.

4. An electromagnetic interference suppressing sheet using the resin composition as defined in claim 3.

5. An electromagnetic interference suppressing sheet according to claim 4, wherein when subjecting the sheet having a thickness of not more than 100 μm to microstrip line measurement, an electromagnetic absorption of the sheet is not less than 10% as measured at 500 MHz and not less than 40% as measured at 3 GHz, and an electromagnetic reflection of the sheet is not more than −5 dB as measured in the range of 100 MHz to 3 GHz.

6. A flat cable for high-frequency signals using the electromagnetic interference suppressing sheet as defined in claim 4.

7. A flexible printed circuit board using the electromagnetic interference suppressing sheet as defined in claim 4.

8. A process for producing an electromagnetic interference suppressing sheet, comprising the steps of applying a coating material in which the conductive magnetic filler as defined in claim 1 is dispersed, onto a substrate; drying the applied coating material to control a thickness of a coating layer obtained therefrom; and subjecting the obtained coated substrate to thermal pressure forming.
